(19) United States
(12) Patent Application Publication
(10) Pub. No.: US 2019/0166690 A1
(43) Pub. Date: May 30, 2019

(54) CERAMIC ELECTRONIC COMPONENT

(71) Applicant: Murata Manufacturing Co., Ltd., Kyoto (JP)

(72) Inventors: Issei YAMAMOTO, Kyoto (JP); Yosuke MATSUSHITA, Kyoto (JP)

(21) Appl. No.: 16/264,882

(22) Filed: Feb. 1, 2019

Related U.S. Application Data
(63) Continuation of application No. PCT/JP2017/027647, filed on Jul. 31, 2017.

(30) Foreign Application Priority Data
Aug. 10, 2016 (JP) 2016-157812

(51) Int. Cl. H05K 1/02; H05K 1/03; H05K 3/46; H05K 3/12; H05K 3/06

(52) U.S. Cl. CPC H05K 1/0298; H05K 1/0306; H05K 2201/0175; H05K 3/1216; H05K 3/06; H05K 3/4644

(57) ABSTRACT

A ceramic electronic component according to the present disclosure includes a wiring formation layer including a ceramic insulation layer containing a low-temperature co-fired ceramic material and a wiring pattern formed on the ceramic insulation layer. The wiring formation layer further has a plurality of dummy patterns formed on a portion of the ceramic insulation layer where the wiring pattern is not formed. The wiring width of the dummy patterns is less than the minimum value of the wiring width of the wiring pattern.

This is a continuation of International Application No. PCT/JP2017/027647 filed on Jul. 31, 2017 which claims priority from Japanese Patent Application No. 2016-157812 filed on Aug. 10, 2016. The contents of these applications are incorporated herein by reference in their entireties.

### BACKGROUND OF THE DISCLOSURE

### Field of the Disclosure

The present disclosure relates to a ceramic electronic component.

### Description of the Related Art

Ceramic electronic components, such as multilayer ceramic substrates and multilayer ceramic capacitors, are produced by using ceramic green sheets.

Patent Document 1 describes that, to avoid the distortion of a substrate caused by a difference in the electrode density between the product portion and the edge portion of a collective board, a product pattern is also disposed on the edge portion during a process of producing a multilayer ceramic substrate by using green sheets.
Patent Document 1: Japanese Unexamined Patent Application Publication No. 2009-200073

### BRIEF SUMMARY OF THE DISCLOSURE

The technique described in Patent Document 1 is for avoiding a mismatch between the electrode density of the product portion of a collective board and the electrode density of the edge portion of the collective board; however, non-uniformity of the electrode density may occur in the product portion depending on the product design.

When a multilayer body in which green sheets are laminated on each other is fired during a process of producing a multilayer ceramic substrate by using green sheets, a ceramic portion shrinks during firing; however, an electrode portion is unlikely to shrink. Thus, the overall shrinkage in a portion where many electrode portions are present is low, and the overall shrinkage in a portion where a few electrode portions are present is high.

Due to the difference in shrinkage in a multilayer body during firing, the delamination and distortion of the shape may occur. In addition, a problem in which the front and rear surfaces of the product become irregular (coplanarity is degraded) may occur.

To satisfy the recent demand for high-density wiring and high-density mounting, non-shrinkage ceramic substrates that do not shrink in the direction of the main surface have been put into practical use. Among the non-shrinkage ceramic substrates, there are substrates including a layer referred to as a restrictive layer that prevents or reduces the shrinkage and that is disposed on a ceramic layer. The adhesive force between the ceramic layer and the restrictive layer is weaker than that between the ceramic layers. Thus, there is a problem in which if the electrode density in a product is non-uniform, the delamination may occur during firing.

The present disclosure has been developed to solve the above problem. An object of the present disclosure is to provide a ceramic electronic component in which structural defects caused by the shrinkage of a ceramic portion and an electrode portion during firing are unlikely to occur.

To achieve the object, a ceramic electronic component according to the present disclosure includes a wiring formation layer including a ceramic insulation layer containing a low-temperature co-fired ceramic material and a wiring pattern formed on the ceramic insulation layer. The wiring formation layer further has a plurality of dummy patterns formed on a portion of the ceramic insulation layer where the wiring pattern is not formed. The wiring width of the dummy patterns is less than the minimum value of the wiring width of the wiring pattern.

In the ceramic electronic component according to the present disclosure, the wiring formation layer having a wiring pattern on a ceramic insulation layer has a plurality of dummy patterns formed on a portion of the ceramic insulation layer where the wiring pattern is not formed.

The wiring width of the dummy patterns is less than the minimum value of the wiring width of the wiring pattern. The dummy patterns are small patterns so as not to affect the electrical characteristics (characteristic impedance and electrostatic capacity) of the electronic component.

When the electrode density is adjusted in a product portion, different from the adjustment of the difference in the electrode density between the product portion and the outside of the product portion, the adjustment of the electrode density needs to be conducted so as not to affect the electrical characteristics of the product. Thus, patterns smaller than a wiring pattern need to be formed instead of patterns having a shape identical to that of a wiring pattern.

A person skilled in the art can distinguish between the wiring pattern and the dummy pattern from, for example, the position of the pattern, the connection mode of the pattern to another wiring, and the shape of the pattern.

The dummy patterns are formed at a portion where the wiring pattern is not formed, so that electrode portions are uniformly distributed in a wiring formation layer, thereby removing non-uniformity of the electrode density.

With such a structure, the occurrence of structural defects caused by non-uniformity of the electrode density during firing can be prevented.

In the ceramic electronic component according to the present disclosure, non-uniformity of the electrode density is removed in each layer.

When the ceramic electronic component according to the present disclosure is a multilayer ceramic substrate, a plurality of wiring formation layers in which non-uniformity of the electrode density is removed are laminated on each other, so that the occurrence of structural defects can be prevented in the overall multilayer ceramic substrate.

It is preferable that the ceramic electronic component according to the present disclosure further include a restrictive layer containing a metal oxide that is not substantially sintered at a sintering temperature of the low-temperature co-fired ceramic material and that the dummy patterns be positioned between the ceramic insulation layer and the restrictive layer.

In a ceramic electronic component including a restrictive layer, the adhesive force between the restrictive layer and a ceramic insulation layer is weak. Thus, there is a concern that the delamination in which the restrictive layer and the ceramic insulation layer are separated from each other may occur during firing. However, the dummy patterns are formed to remove non-uniformity of the electrode density, so that non-uniformity of the stress applied to a portion between the restrictive layer and the ceramic insulation layer can be decreased. As a result, the occurrence of the delamination in which the restrictive layer and the ceramic insulation layer are separated from each other can be prevented.

In the ceramic electronic component according to the present disclosure, the dummy patterns are preferably arranged at a density of 10 pieces/mm² or more and 400 pieces/mm² or less.

The expression “the density at which the dummy patterns are arranged is within the range” indicates that the dummy patterns are fine. Fine dummy patterns affect neither electrical characteristics (characteristic impedance and electrostatic capacity) nor coplanarity.

In the ceramic electronic component according to the present disclosure, the composition of the material constituting the dummy patterns is preferably identical to the composition of the material constituting the wiring pattern.

The composition of the material constituting the dummy patterns is identical to the composition of the material constituting the wiring pattern, so that the wiring pattern and the dummy patterns can be formed at the same time. This is advantageous in terms of the production process.

In the ceramic electronic component according to the present disclosure, the composition of the material constituting the dummy patterns is preferably different from the composition of the material constituting the wiring pattern.

The composition of the material constituting the dummy pattern is adjusted, so that shrinkage of the dummy-pattern portion during firing can be adjusted. This provides a ceramic electronic component in which the occurrence of structural defects during firing is more reliably prevented.

In the ceramic electronic component according to the present disclosure, the dummy patterns are preferably patterns disposed at identical pitches.

The dummy patterns are disposed at identical pitches, so that stress that occurs due to the shrinkage of a low-temperature co-fired ceramic material during firing can be uniformly decreased. This provides a ceramic electronic component in which the occurrence of structural defects during firing is more reliably prevented.

In the ceramic electronic component according to the present disclosure, it is preferable that a plurality of the wiring formation layers be disposed and that arrangements of the dummy patterns in the wiring formation layers be identical to each other.

The arrangements of the dummy patterns in the wiring formation layers are identical to each other, so that the dummy patterns can be printed by using an identical screen-printing plate. Thus, the production cost is reduced.

When the dummy patterns are formed by photolithography, the identical mask can be used, thereby reducing the production cost.

In the ceramic electronic component according to the present disclosure, it is preferable that a plurality of the wiring formation layers be disposed and that arrangements of the dummy patterns in the wiring formation layers be different from each other.

The arrangements of the dummy patterns in the wiring formation layers are different from each other, so that positions where the stress occurs due to the shrinkage during firing can be dispersed in each layer. Thus, the occurrence of structural defects is further prevented or reduced.

In the ceramic electronic component according to the present disclosure, the plurality of dummy patterns formed on the identical ceramic insulation layer preferably have an identical shape.

The dummy patterns have an identical shape, so that the stress applied due to the shrinkage during firing to a portion where the dummy patterns are formed is uniformly decreased. Thus, the occurrence of structural defects is further prevented or reduced.

According to the present disclosure, a ceramic electronic component in which structural defects caused by the shrinkage of a ceramic portion and an electrode portion during firing are unlikely to occur is provided.

### BRIEF DESCRIPTION OF THE SEVERAL VIEWS OF THE DRAWINGS

FIG. 1 is a schematic cross-sectional view of one example of a wiring formation layer constituting a ceramic electronic component.

FIG. 2 is a schematic plan view of one example of the wiring formation layer.

Each of FIG. 3A, FIG. 3B, FIG. 3C, FIG. 3D, and FIG. 3E is a schematic plan view of one example of the shape of a dummy pattern.

FIG. 4 is a schematic cross-sectional view of one example of a multilayer ceramic substrate including the wiring formation layer.

FIG. 5A is a schematic cross-sectional view of an arrangement of the dummy patterns in a case where the arrangements of the dummy patterns at the wiring formation layers are identical to each other. FIG. 5B is a schematic cross-sectional view of the arrangement of the dummy patterns in a case where the arrangements of the dummy patterns at the wiring formation layers are different from each other.

FIG. 6 is a schematic cross-sectional view of one example of a multilayer ceramic substrate including a restrictive layer.

### DETAILED DESCRIPTION OF THE DISCLOSURE

Hereinafter, a ceramic electronic component according to the present disclosure will be described.

However, the present disclosure is not limited to the following configurations. Various modifications may be appropriately made as long as the gist of the present disclosure is not changed.

A combination of two or more individual desirable configurations of the present disclosure described below is also included in the present disclosure.

The following embodiments are illustrative. Obviously, partial substitution or combination of the configurations of different embodiments is possible.

As one embodiment of the ceramic electronic component according to the present disclosure, a multilayer ceramic substrate will be described.

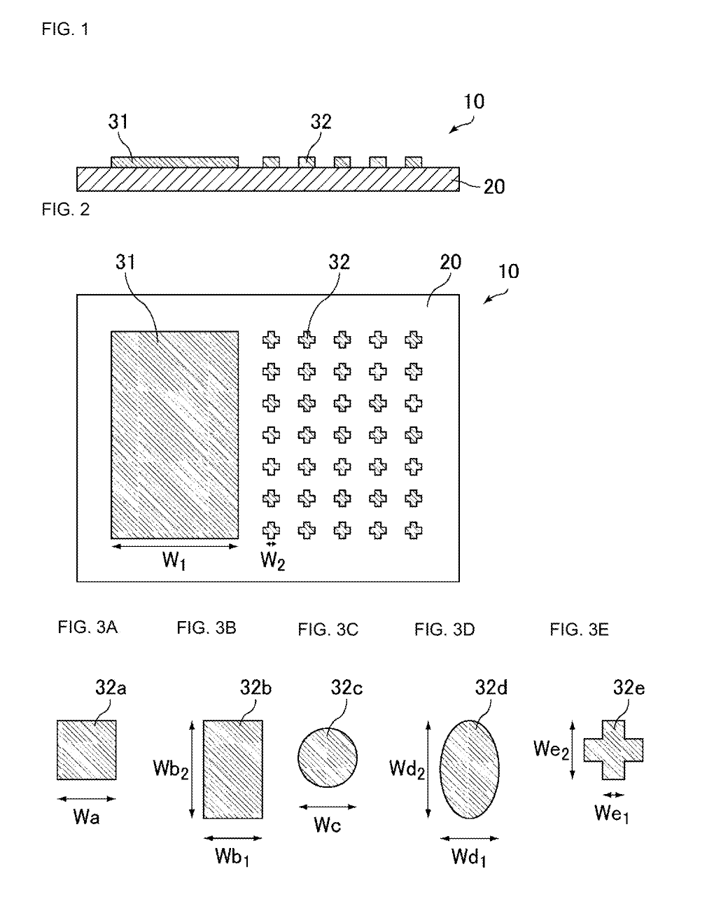

FIG. 1 is a schematic cross-sectional view of one example of a wiring formation layer constituting the ceramic electronic component.

A wiring formation layer 10 includes a ceramic insulation layer 20 containing a low-temperature co-fired ceramic material and a wiring pattern 31 formed on the ceramic insulation layer 20. In FIG. 1, the wiring pattern 31 is formed on the left side of the ceramic insulation layer 20, but not on the right side of the ceramic insulation layer 20.

A plurality of dummy patterns 32 are formed on a portion of the ceramic insulation layer 20 where the wiring pattern 31 is not formed.

FIG. 2 is a schematic plan view of one example of the wiring formation layer.

FIG. 2 shows that the wiring pattern 31 and the plurality of dummy patterns 32 are formed on the ceramic insulation layer 20. The dummy pattern 32 has a cross shape. The cross-shaped dummy patterns 32 are disposed at identical pitches. The plurality of dummy patterns 32 have an identical shape.

The dummy pattern 32 is a pattern having a wiring width (denoted by double-headed arrow W₂ in FIG. 2) less than the minimum value of the wiring width of the wiring pattern 31 (denoted by double-headed arrow W₁ in FIG. 2).

When the wiring pattern and the dummy pattern each have a shape having a plurality of dimensions that may be regarded as the wiring width thereof, the wiring width is assumed to be the minimum dimension among the plurality of dimensions. The relations between the dummy patterns and the wiring pattern can be determined by using the wiring width.

Specific examples of determining the wiring width of the dummy pattern will be fully described later.

The dummy patterns are disposed so as to decrease non-uniformity of the electrode density caused by the placement of the wiring pattern.

Parameters for adjusting the electrode density include the density at which dummy patterns are arranged, the pitch, shape, size, and thickness of the dummy patterns.

The dummy patterns are preferably arranged at a density of 10 pieces/mm² or more and 400 pieces/mm² or less. The dummy patterns arranged at a density within the range are small so as to be referred to as fine patterns. Such fine dummy patterns do not affect the electrical characteristics.

When the pitch of the dummy patterns is decreased to increase the density at which the dummy patterns are arranged, the electrode density can be increased; however, if the pitch is very small, the electrical characteristics may be affected, and thus, the pitch is preferably set to be not very small.

The pitch of the dummy patterns refers to the distance between the centers of adjacent dummy patterns.

The appropriate pitch is 50 μm or more and 400 μm or less. The pitches of the plurality of dummy patterns are preferably identical to each other.

Each of FIG. 3A, FIG. 3B, FIG. 3C, FIG. 3D, and FIG. 3E is a schematic plan view of one example of the shape of the dummy pattern.

FIG. 3A shows a dummy pattern 32a having a square shape in a plan view. The wiring width of the dummy pattern 32a is a dimension (the length of one side of the square) denoted by double-headed arrow Wa.

FIG. 3B shows a dummy pattern 32b having a rectangular shape in a plan view. The wiring width of the dummy pattern 32b is a dimension (the length of the short side of the rectangular) denoted by double-headed arrow Wb₁.

FIG. 3C shows a dummy pattern 32c having a circular shape in a plan view. The wiring width of the dummy pattern 32c is a dimension (the diameter of the circle) denoted by double-headed arrow Wc.

FIG. 3D shows a dummy pattern 32d having an elliptic shape in a plan view. The wiring width of the dummy pattern 32d is a dimension (the minor axis of the ellipse) denoted by double-headed arrow Wd₁.

FIG. 3E shows a dummy pattern 32e having a cross shape in a plan view. The wiring width of the dummy pattern 32e is a dimension (the width of the line constituting the cross) denoted by double-headed arrow We₁.

Among such shapes, a cross shape is preferable.

When the dummy pattern has a cross shape, the stress can particularly be adjusted in four directions in which electrodes are present. Thus, if the stress balance is non-uniform in the surface, the cross is rotated to adjust the balance.

When the size of the dummy pattern is large, the electrode density is increased; however, if the size is very large, the electrical characteristics may be affected, and thus, the size is preferably set to be not very large.

The appropriate size of the dummy pattern is such that the maximum width is 1 μm or more and 30 μm or less.

The maximum width of the square dummy pattern in FIG. 3A is identical to the wiring width Wa. The maximum width of the circular dummy pattern in FIG. 3C is identical to the wiring width Wc.

The maximum width of the rectangular dummy pattern in FIG. 3B is the dimension (the length of the long side of the rectangular) denoted by double-headed arrow Wb₂. The maximum width of the elliptic dummy pattern in FIG. 3D is the dimension (the major axis of the ellipse) denoted by double-headed arrow Wd₂. The maximum width of the cross-shape dummy pattern in FIG. 3E is the dimension (the length of the line constituting the cross) denoted by double-headed arrow We₂.

In the ceramic electronic component according to the present disclosure, a plurality of dummy patterns having the above-described shape are disposed on a ceramic insulation layer. The dummy patterns may have different shapes or an identical shape; however, the plurality of dummy patterns formed on the identical ceramic insulation layer preferably have an identical shape.

The thickness of the dummy pattern is not particularly limited, but is preferably 1 μm or more and 10 μm or less. When the dummy pattern is thick, the electrode density can be increased; however, if the dummy pattern is very thick, a short circuit may occur between the layers.

As the material constituting the dummy pattern, a conductive material used for ceramic electronic components produced by using a low-temperature co-fired ceramic material is suitably used.

A metal material is preferably contained as the conductive material. In addition, a ceramic material or a glass material may be added.

As the metal material, Au, Ag, or Cu is preferably contained, and Ag or Cu is more preferably contained.

Examples of the ceramic material include alumina, titania, and silica.

Examples of the glass material include quartz glass and borosilicate glass.

The composition of the material constituting the above-described dummy patterns may be identical to or different from the composition of the material constituting the wiring pattern.

The conductive material used for ceramic electronic components produced by using a low-temperature co-fired ceramic material, which is used as the material constituting the dummy pattern, is also suitably used as the material constituting the wiring pattern. A metal material is preferably contained as the conductive material. In addition, a ceramic material or a glass material may be added.

As the metal material, Au, Ag, or Cu is preferably contained, and Ag or Cu is more preferably contained. Au, Ag, and Cu have low resistivity and are thus particularly suitable for ceramic electronic components for high-frequency applications.

Examples of the ceramic material include alumina, titania, and silica.

Examples of the glass material include quartz glass and borosilicate glass.

The ceramic insulation layer contains a low-temperature co-fired ceramic material.

Examples of the low-temperature co-fired ceramic material include glass-composite-based low-temperature co-fired ceramic materials produced by mixing borosilicate glass with quartz or a ceramic material, such as alumina or forsterite, crystallized-glass-based low-temperature co-fired ceramic materials produced by using a ZnO—MgO—Al₂O₃—SiO₂-based crystallized-glass, and non-glass-based low-temperature co-fired ceramic materials produced by using, for example, a BaO—Al₂O₃—SiO₂-based ceramic material or an Al₂O₃—CaO—SiO₂—MgO—B₂O₃-based ceramic material.

Examples of a layer, other than the wiring formation layer, that can constitute the ceramic electronic component include a dummy pattern layer in which only dummy patterns are uniformly formed on the ceramic insulation layer so as not to make the electrode density non-uniform, a non-pattern layer in which neither dummy patterns nor wiring patterns are formed on the ceramic insulation layer, and a uniform wiring layer in which only wiring patterns are uniformly formed on the ceramic insulation layer so as not to make the electrode density non-uniform.

A preferable aspect of forming dummy patterns in the dummy pattern layer is identical to the aspect of forming dummy patterns in the wiring formation layer.

These layers are layers in which the electrode density is uniform on the ceramic insulation layer.

When the ceramic electronic component according to the present disclosure includes such a layer in addition to the wiring formation layer, the ceramic electronic component can be a product in which each layer has a uniform electrode density. Such a product has a uniform electrode density as a whole, so that the occurrence of structural defects caused by the shrinkage during firing can be prevented.

Layers including the wiring formation layer that constitute the ceramic electronic component may each include a via conductor to connect the layers together.

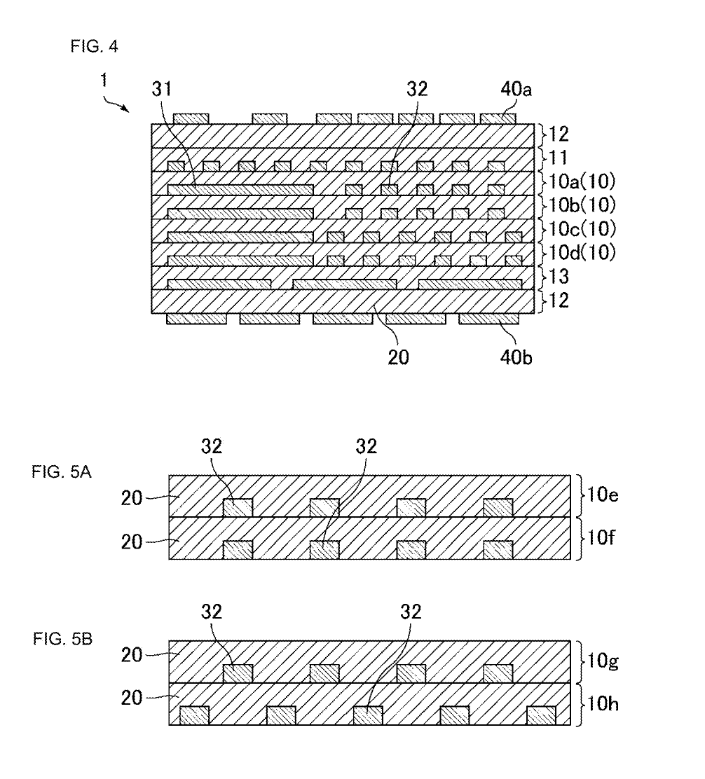

FIG. 4 is a schematic cross-sectional view of one example of a multilayer ceramic substrate including the wiring formation layer.

A multilayer ceramic substrate 1 includes the wiring formation layers 10 in FIG. 1 (a wiring formation layer 10a, a wiring formation layer 10b, a wiring formation layer 10c, and a wiring formation layer 10d). A plurality of wiring formation layers 10 are formed in the multilayer ceramic substrate 1.

The wiring formation layer 10 includes the wiring pattern 31 and the dummy patterns 32 formed on the ceramic insulation layer 20. When the ceramic electronic component according to the present disclosure is a multilayer ceramic substrate, it is not necessary that all layers have a structure of the wiring formation layer 10.

FIG. 4 shows that layers other than the wiring formation layer, such as a dummy pattern layer 11, a non-pattern layer 12, and a uniform wiring layer 13, are laminated with the wiring formation layers.

FIG. 4 shows the wiring formation layer 10 formed of the wiring pattern 31, the dummy patterns 32, and the ceramic insulation layer 20 in which the wiring pattern 31 and the dummy patterns 32 are buried. In other words, the wiring formation layer 10 in FIG. 4 is upside down with respect to that in FIG. 1. The ceramic insulation layer 20 is on the upper side, and the wiring pattern 31 and the dummy patterns 32 are on the lower side. The dummy pattern layer 11, the non-pattern layer 12, and the uniform wiring layer 13 are shown in an identical direction, and the ceramic insulation layers in such layers are also on the upper side.

On the outermost surface of the multilayer ceramic substrate 1, outer conductors 40a (outer conductors shown on the upper side of FIG. 4) and outer conductors 40b (outer conductors shown on the lower side of FIG. 4) are disposed.

A multilayer ceramic capacitor or an IC that serves as a chip component (not shown) may be placed on the outer conductor 40a. A bonding material, such as solder, may be used to place a chip component on the outer conductor 40a. The outer conductor 40b is used as an electrical connecting member when the multilayer ceramic substrate 1, on which the chip component is placed, is mounted on a motherboard (not shown).

In the ceramic electronic component according to the present disclosure, the arrangements of the dummy patterns in the wiring formation layers may be identical to each other, or the arrangements of the dummy patterns in the wiring formation layers may be different from each other.

FIG. 4 is a view of the multilayer ceramic substrate 1 in which a plurality of wiring formation layers are formed. FIG. 4 also shows layers in which the arrangements of the dummy patterns are identical to each other and layers in which the arrangements of the dummy patterns are different from each other. Specifically, the wiring formation layer 10a and the wiring formation layer 10b are wiring formation layers in which the arrangements of the dummy patterns are identical to each other. The wiring formation layer 10c and the wiring formation layer 10d are wiring formation layers in which the arrangements of the dummy patterns are identical to each other.

On the other hand, the arrangements of the dummy patterns in the wiring formation layer 10a and the wiring formation layer 10b are different from the arrangements of the dummy patterns in the wiring formation layer 10c and the wiring formation layer 10d.

In the present disclosure, the expression “a plurality of wiring formation layers are disposed in a ceramic electronic component, and the arrangements of the dummy patterns in the wiring formation layers are identical to each other” does not indicate that the arrangements of the dummy patterns in all wiring formation layers are identical to each other, but indicates that the arrangements of the dummy patterns in at least two wiring formation layers are identical to each other.

In the multilayer ceramic substrate 1 shown in FIG. 4, the arrangements of the dummy patterns in the wiring formation layer 10a and the wiring formation layer 10b are identical to each other, and thus, the multilayer ceramic substrate 1 satisfies the condition of the expression “a plurality of wiring formation layers are disposed in a ceramic electronic component, and the arrangements of the dummy patterns in the wiring formation layers are identical to each other”, regardless of the arrangements of the dummy patterns in other wiring formation layers (the wiring formation layer 10c and the wiring formation layer 10d).

In the present disclosure, the expression “a plurality of wiring formation layers are disposed in the ceramic electronic component, and the arrangements of the dummy patterns in the wiring formation layers are different from each other” does not indicate that the arrangements of the dummy patterns in all wiring formation layers are different from each other, but indicates that the arrangements of the dummy patterns in at least two wiring formation layers are different from each other.

In the multilayer ceramic substrate 1 shown in FIG. 4, the arrangements of the dummy patterns in the wiring formation layer 10b and the wiring formation layer 10c are different from each other, and thus, the multilayer ceramic substrate 1 satisfies the condition of the expression “a plurality of wiring formation layers are disposed in a ceramic electronic component, and the arrangements of the dummy patterns in the wiring formation layers are different from each other”, regardless of the arrangements of the dummy patterns in other wiring formation layers (the wiring formation layer 10a and the wiring formation layer 10d).

A technical advantage exhibited when the arrangements of the dummy patterns in the wiring formation layers are identical to each other will be described with reference to FIG. 5A. A technical advantage exhibited when the arrangements of the dummy patterns in the wiring formation layers are different from each other will be described with reference to FIG. 5B.

FIG. 5A is a schematic cross-sectional view of the arrangement of the dummy patterns in a case where the arrangements of the dummy patterns in the wiring formation layers are identical to each other.

FIG. 5A shows that a wiring formation layer 10e in which the dummy patterns 32 are formed and a wiring formation layer 10f in which the dummy patterns 32 are formed are laminated on each other.

In the wiring formation layer 10e and the wiring formation layer 10f, the arrangements of the dummy patterns are identical to each other in the vertical direction.

The arrangements of the dummy patterns in wiring formation layers are identical to each other as described above, so that the dummy patterns can be printed by using an identical screen-printing plate. Thus, the production cost can be reduced.

For an advantage exhibited when the arrangements of the dummy patterns are identical to each other to be realized, a wiring pattern is also printed by using an identical screen-printing plate, and thus, the arrangements of wiring patterns in the wiring formation layers are also identical to each other.

FIG. 5B is a schematic cross-sectional view of the arrangement of the dummy patterns in a case where the arrangements of the dummy patterns in the wiring formation layers are different from each other.

FIG. 5B shows that a wiring formation layer 10g in which the dummy patterns 32 are formed and a wiring formation layer 10h in which the dummy patterns 32 are formed are laminated on each other.

In the wiring formation layer 10g and the wiring formation layer 10h, the arrangements of the dummy patterns are different from each other in the vertical direction.

The arrangements of the dummy patterns in wiring layers are different from each other, so that positions where the stress occurs due to the shrinkage during firing can be dispersed in each layer. Thus, the occurrence of structural defects can be further prevented or reduced.

The ceramic electronic component according to the present disclosure may further include a restrictive layer containing a metal oxide that is not substantially sintered at the sintering temperature of a low-temperature co-fired ceramic material. The dummy patterns may be positioned between a ceramic insulation layer and the restrictive layer.

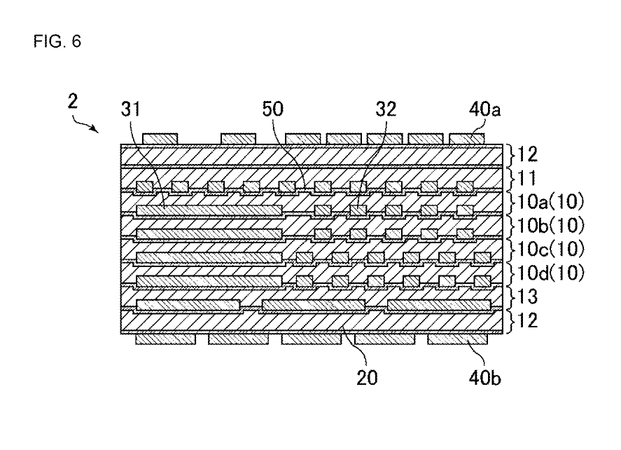

FIG. 6 is a schematic cross-sectional view of one example of a multilayer ceramic substrate including a restrictive layer.

As well as the multilayer ceramic substrate 1 shown in FIG. 4, a multilayer ceramic substrate 2, shown in FIG. 6, includes the wiring formation layers 10. The multilayer ceramic substrate 2 has the same structure as the multilayer ceramic substrate 1 in FIG. 4, except that a restrictive layer 50 is disposed between the ceramic insulation layers 20.

The restrictive layer 50 contains a metal oxide that is not substantially sintered at the sintering temperature of a low-temperature co-fired ceramic material.

Examples of a metal oxide that is not substantially sintered at the sintering temperature of a low-temperature co-fired ceramic material include alumina, silica, zirconia, titania, silica, niobium pentoxide, tantalum pentoxide, and magnesia. Among such metal oxides, alumina and silica are preferable. In consideration of high-frequency characteristics of the ceramic component, such metal oxides may be used alone or in a combination of two or more mixed together.

The restrictive layer preferably contains glass in addition to the metal oxide. Examples of the glass contained in the restrictive layer include B—Si-M-based glass (M is an alkali metal or an alkaline-earth metal).

It is not necessary that the restrictive layer be disposed between all ceramic insulation layers.

In a ceramic electronic component including a restrictive layer, the adhesive force between the restrictive layer and a ceramic insulation layer is weak. Thus, there is a concern that the delamination in which the restrictive layer and the ceramic insulation layer are separated from each other may occur during firing. However, the dummy patterns are formed to remove non-uniformity of the electrode density, so that non-uniformity of the stress applied to a portion between the restrictive layer and the ceramic insulation layer can be decreased. As a result, the occurrence of the delamination in which the restrictive layer and the ceramic insulation layer are separated from each other can be prevented.

A multilayer ceramic substrate is described here as one embodiment of the ceramic electronic component according to the present disclosure; however, the ceramic electronic component according to the present disclosure may be a chip component.

Examples of the chip component include chip components placed on a multilayer ceramic substrate, for example, multilayer ceramic electronic components, such as multilayer ceramic capacitors, multilayer inductors, and multilayer filters. The present disclosure can also be applied to various ceramic electronic components other than multilayer ceramic electronic components.

The ceramic electronic component according to the present disclosure is a ceramic electronic component in which structural defects are unlikely to occur and is thus a ceramic electronic component with good coplanarity.

The coplanarity of the multilayer ceramic substrate is preferably 20 μm or less, and the coplanarity of the chip component is preferably 50 μm or less.

Subsequently, an example of the method for producing the ceramic electronic component according to the present disclosure will be described.

Hereinafter, the method for producing the multilayer ceramic substrate 1 in the FIG. 4 will be described.

(1) A green sheet containing a low-temperature co-fired ceramic material is produced.

A binder, a plasticizer and a ceramic powder containing a low-temperature co-fired ceramic material are mixed at an arbitrary ratio to produce a ceramic slurry.

The ceramic slurry is applied to a carrier film to form a sheet.

Devices, such as a lip coater or a doctor blade, may be used to apply the slurry.

The thickness of the ceramic green sheet to be produced is arbitrary, but preferably 5 μm or more and 100 μm or less.

(2) A layer-connecting portion is formed at a predetermined portion of the green sheet.

In response to the shape of the wiring pattern, a hole is formed and processed in the green sheet by using, for example, a mechanical puncher, a CO₂ laser, or a UV laser, as needed. The diameter of the hole is arbitrary, but preferably 20 μm or more and 200 μm or less.

Subsequently, the hole is filled with a conductive paste. A conductive paste containing a conductive powder, a plasticizer, and a binder is used as the conductive paste.

A common base material (ceramic powder) for adjusting the shrinkage ratio may be added to the conductive paste.

(3) A wiring pattern is formed.

A wiring pattern is formed on the green sheet.

The formation of a wiring pattern can be performed by screen printing. The wiring pattern is printed with the conductive paste containing a conductive powder, a plasticizer, and a binder.

As the conductive paste for forming a wiring pattern that serves as a ground, a conductive paste to which a common base material (ceramic or glass) is further added for adjusting shrinkage with respect to the shrinkage of ceramics is preferably used.

A wiring pattern may be formed by, for example, ink-jet printing, gravure printing, or photolithography, other than screen printing.

Photolithography for forming a wiring pattern can be performed by solid printing using a photosensitive conductive paste, exposing, and developing. As the photosensitive conductive paste, a photosensitive conductive paste containing a metal material and photosensitive organic components (an alkali-soluble polymer, a photosensitive monomer, and a photopolymerization initiator) can be used.

(4) Dummy patterns are formed.

Dummy patterns can also be formed by screen printing. The dummy patterns and the wiring pattern may be printed simultaneously or separately.

The conductive paste may be identical to or different from that used for forming the wiring pattern.

When the identical conductive paste is used, the wiring pattern and the dummy patterns can be printed at the same time. This is advantageous in terms of the process.

The dummy patterns can also be formed by, for example, ink-jet printing, gravure printing, or photolithography.

The wiring pattern and the dummy patterns may differ from each other in terms of the formation method.

Photolithography for forming the dummy patterns can be performed by solid printing using a photosensitive conductive paste followed by exposing and developing so as to leave the dummy patterns.

Etching conditions during production of the wiring pattern are adjusted to perform etching such that a slight amount of solid-printing portion remains, so that fine dummy patterns can be formed. The etching conditions can be adjusted by adjusting the etching time, composition or concentration of the etching solution, and temperature conditions.

(5) Green sheets are laminated on each other to form a multilayer body.

The green sheet in which the wiring pattern and dummy patterns are formed in the above process is a green sheet that is to be the wiring formation layer. This green sheet and another green sheet that is to be another layer (e.g., a dummy pattern layer, a non-pattern layer, or a uniform wiring layer) are provided as needed and layered on each other. The number of layers is arbitrary.

The green sheets are laminated with a surface where the wiring pattern and the dummy patterns are formed facing downward and pressure-bonded, so that a multilayer body in which the wiring patterns and the dummy patterns are arranged as shown in FIG. 4 can be produced.

(6) The multilayer body is pressure-bonded.

The multilayer body is placed in a mold and pressure-bonded. The pressure and temperature can be arbitrarily set.

(7) The pressure-bonded multilayer body is fired.

The multilayer body is disposed in a sagger for firing and fired. A batch furnace or a belt furnace can be used as a firing furnace.

When copper is used as a conductive material constituting the wiring pattern and the dummy patterns, firing is preferably performed in a reducing atmosphere.

The outer conductor is preferably subjected to plating as needed after fired. The plating can be selected from, for example, Ni—Sn plating and electroless Au plating.

A break line is preferably formed as needed before firing. A method for forming the break line can be selected from methods using, for example, a laser cutter, a guillotine cutter (half cut), and a dicer (half cut).

A multilayer ceramic substrate serving as a ceramic electronic component can be produced according to the above-described process.

An IC or a SMD (surface mount device) can be mounted on the produced multilayer ceramic substrate, and thereafter, sealing with a resin can be performed.

When a ceramic electronic component including a restrictive layer, such as the multilayer ceramic substrate 2 in FIG. 6, is produced, a green sheet with a restrictive layer is produced by using a slurry for the restrictive layers.

The slurry for the restrictive layers is a slurry in which a ceramic powder having a composition adjusted so as to have a sintering temperature higher than that of the low-temperature co-fired ceramic material constituting the ceramic slurry described in (1), a binder, and a plasticizer are mixed together at an arbitrary ratio.

Examples of a method for raising the sintering temperature include a method in which the amount of glass component is decreased and a method in which the mixing ratio of the ceramic component, such as alumina, is increased.

The slurry for the restrictive layers and a ceramic slurry are sequentially applied to a carrier film to form a sheet, and a green sheet with a restrictive layer is produced.

The restrictive layer preferably has a thickness of 0.1 or more and 5 μm or less.

The ceramic electronic component including a restrictive layer can be produced by subsequently performing the identical process by using the green sheet with a restrictive layer.

Note that when the green sheet with a restrictive layer is produced, the ceramic slurry may be applied first, and then the slurry for the restrictive layers may be applied.
1, 2 multilayer ceramic substrate (ceramic electronic component)
10, 10a, 10b, 10c, 10d, 10e, 10f, 10g, 10h wiring formation layer
20 ceramic insulation layer
31 wiring pattern
32, 32a, 32b, 32c, 32d, 32e dummy pattern
50 restrictive layer

1. A ceramic electronic component comprising at least one wiring formation layer including a ceramic insulation layer containing a low-temperature co-fired ceramic material and a wiring pattern provided on the ceramic insulation layer,
wherein the at least one wiring formation layer further has a plurality of dummy patterns provided on a portion of the ceramic insulation layer where the wiring pattern is not provided, and
a wiring width of the dummy patterns is less than a minimum value of a wiring width of the wiring pattern.

2. The ceramic electronic component according to claim 1, further comprising a restrictive layer containing a metal oxide not substantially sintered at a sintering temperature of the low-temperature co-fired ceramic material,
wherein the dummy patterns are positioned between the ceramic insulation layer and the restrictive layer.

3. The ceramic electronic component according to claim 1, wherein the dummy patterns are arranged at a density of 10 pieces/mm² or more and 400 pieces/mm² or less.

4. The ceramic electronic component according to claim 1, wherein a composition of a material constituting the dummy patterns is identical to a composition of a material constituting the wiring pattern.

5. The ceramic electronic component according to claim 1, wherein a composition of a material constituting the dummy patterns is different from a composition of a material constituting the wiring pattern.

6. The ceramic electronic component according to claim 1, wherein the dummy patterns are patterns disposed at identical pitches.

7. The ceramic electronic component according to claim 1, wherein the at least one wiring formation layer comprises a plurality of wiring formation layers, and
arrangements of the dummy patterns in each of the plurality of wiring formation layers are identical to each other.

8. The ceramic electronic component according to claim 1, wherein the at least one wiring formation layer comprises a plurality of wiring formation layers, and
arrangements of the dummy patterns in each of the plurality of wiring formation layers are different from each other.

9. The ceramic electronic component according to claim 1, wherein the plurality of dummy patterns provided on the ceramic insulation layer have an identical shape.

10. The ceramic electronic component according to claim 2, wherein the dummy patterns are arranged at a density of 10 pieces/mm² or more and 400 pieces/mm² or less.

11. The ceramic electronic component according to claim 2, wherein a composition of a material constituting the dummy patterns is identical to a composition of a material constituting the wiring pattern.

12. The ceramic electronic component according to claim 3, wherein a composition of a material constituting the dummy patterns is identical to a composition of a material constituting the wiring pattern.

13. The ceramic electronic component according to claim 2, wherein a composition of a material constituting the dummy patterns is different from a composition of a material constituting the wiring pattern.

14. The ceramic electronic component according to claim 3, wherein a composition of a material constituting the dummy patterns is different from a composition of a material constituting the wiring pattern.

15. The ceramic electronic component according to claim 2, wherein the dummy patterns are patterns disposed at identical pitches.

16. The ceramic electronic component according to claim 3, wherein the dummy patterns are patterns disposed at identical pitches.

17. The ceramic electronic component according to claim 4, wherein the dummy patterns are patterns disposed at identical pitches.

18. The ceramic electronic component according to claim 5, wherein the dummy patterns are patterns disposed at identical pitches.
